(19) United States
(12) Patent Application Publication
(10) Pub. No.: US 2015/0059827 A1
(43) Pub. Date: Mar. 5, 2015

(54) Torque Tube for Solar Panel System

(71) Applicant: JSI Equipment Solutions LLC, Boulder, CO (US)

(72) Inventors: Max W. Reed, Longmont, CO (US); Brian D. Kirtland, Boulder, CO (US)

(73) Assignee: JSI Equipment Solutions LLC, Boulder, CO (US)

(21) Appl. No.: 14/013,999

(22) Filed: Aug. 29, 2013

(51) Int. Cl. H01L 31/052

(52) U.S. Cl. CPC H01L 31/0522
USPC 136/246

(57) ABSTRACT

A solar panel array system has a torque tube supported on upper ends of vertical posts. The torque tube has an octagonal exterior surface and an octagonal interior surface corresponding with the exterior surface. The octagonal exterior surface defines at least one flat datum surface for mounting a photo-voltaic panel. A weld seam extends along the exterior surface parallel with the longitudinal axis.

### FIELD OF THE DISCLOSURE

This invention relates in general to torque tubes on which solar or photo-voltaic panels are mounted for rotation with the torque tube.

### BACKGROUND

Solar or photo-voltaic panels may be installed with a tracking system to pivot and track the sun during the day. One type of system has parallel rows of panels, each row extending north and south. The solar panels or modules in each row are mounted on a torque or torsion tube for rotation with the tube. Each row has a separate torque tube, which may have a length of 200 feet or more. A drive shaft extends perpendicular to the torque tubes and has mechanical devices that convert movement of the drive shaft into rotation of the torque tube. A controller programmed to track the sun operates the drive shaft.

The torque tube is supported on several posts, each of which has a bearing on its upper end. Because of the length, the drive system has to apply significant torque to rotate the torque tubes. Also, wind blowing against the solar panels generates torque along the lengths of the torque tubes that is transferred to the drive system.

The solar panels in each row must be installed on the torque tube in the same plane, and they must stay in the same plane during operation. Consequently, the torque tubes must be very stiff in torsion. A stiffer torque tube allows less twist out at the free ends of the torque tube as compared to a more compliant torque tube, which would allow more twist.

Since the solar panels must be mounted to the torque tube in a single plane, preferably the torque tube has a datum surface or reference for orienting the panels while they are being attached. Having a fixed datum surface extending along the length of the torque tube facilitates the installer installing the solar panels in the same plane. For example, it is difficult to mount flat solar panels on a cylindrical torque tube in a single plane and so as to be able to transmit torque due to wind. Normally, brackets would have to be welded to a cylindrical torque tube to provide the datum surface. As a result most solar array systems employ torque tubes with a square cross-sectional configuration. One of the flat sides becomes the datum surface, and clamping a panel to the flat side so as to be able to withstand torque is not difficult.

### SUMMARY

A solar panel array system has plurality of vertical posts. A torque tube is supported on upper ends of the vertical posts. The torque tube has a cross-sectional configuration having an exterior surface with more than four flat sides. A photo-voltaic module clamp fastens to one of the flat sides.

The flat side to which the photo-voltaic mount is fastened preferably has a width that is no greater than 40 percent a cross-sectional dimension of the exterior surface of the torque tube measured along a line passing through the longitudinal axis. In the preferred embodiment, each of the flat sides of the exterior surface of the torque tube has an interior surface that is also flat and of the same dimensions as on the exterior surface. Preferably, the torque tube has a uniform wall thickness. In one embodiment, a cross-sectional dimension of the exterior surface of the torque tube measuring along a line passing through the axis is at least 30 times the wall thickness.

In the preferred embodiment, the torque tube is roll formed from a flat sheet. A weld seam extends along one of the flat sides parallel with the longitudinal axis.

The exterior surface of the torque tube may be an octagon with eight flat sides. Each of the flat sides joins two other of the flat sides and has an identical width.

### BRIEF DESCRIPTION OF THE DRAWINGS

FIG. 1 is a schematic illustration of a photo-voltaic panel tracking system in accordance with this disclosure.

FIG. 2 is a schematic isometric view of a torque tube rotatably mounted by a bearing on a post of the tracking system of FIG. 1.

FIG. 3 is an sectional view of the torque tube of FIG. 2 with part of a solar module clamped on it.

FIG. 4 is a graph of shear stress due to torsion for torque tubes of circular, octagonal and square cross-section.

FIG. 5 is a graph of angle of twist due to torsion for torque tubes of circular, octagonal and square cross-section.

FIG. 6 is a graph of deflection due to bending for torque tubes of circular, octagonal and square cross-section.

### DETAILED DESCRIPTION OF THE DISCLOSURE

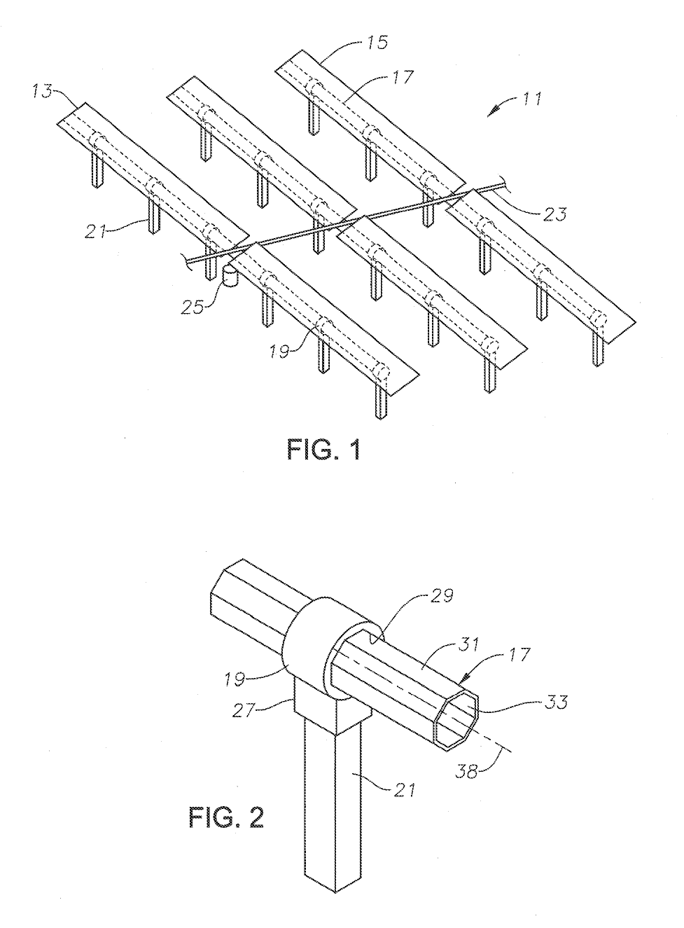

Referring to FIG. 1, solar array system 11 is of a type having the ability to track the sun during the day. Solar array system 11 has several parallel rows 13 (three shown) aligned in a north-south direction. In each row 13, solar panels 15, also called photo-voltaic panels or modules, are mounted on a torque tube 17, which extends in a north-south direction. Each torque tube 17 may extend from one end to the other end of one of the rows 13, or each torque tube 17 may have sections coupled together with flexible joints or field-welded to each other. Torque tubes 17 rotate incrementally, causing solar panels 15 to tilt and remain in better exposure to the sun.

Torque tubes 17 are mounted by bearings 19 to vertical posts 21. Posts 21 are embedded in the earth or a provided foundation at selected distances apart from each other. A drive shaft 23 driven by a drive unit 25 extends perpendicular to rows 13 and engages each torque tube 17 to cause pivotal rotation of each torque tube 17. Drive shaft 23 may rotate or may move linearly. Drive shaft 23 is illustrated as engaging torque tubes 17 midway along the lengths of each row 13. Each torque tube 17, may for example be 100 to 200 feet in length or more, and posts 21 may be about 14-19 feet apart from each other. Torque tube 17 is typically made up of sections about 30 feet in length that are joined in the field by articulating joints or welding.

Referring to FIG. 2, bearing 19 is shown schematically and may be a variety of configurations. Bearing 19 is mounted on a bracket 27 that secures to the upper end of one of the posts 21. Bearing 19 has a cavity 29 through which toque tube 17 extends. Cavity 29 is polygonal, having more than four flat sides, and preferably eight.

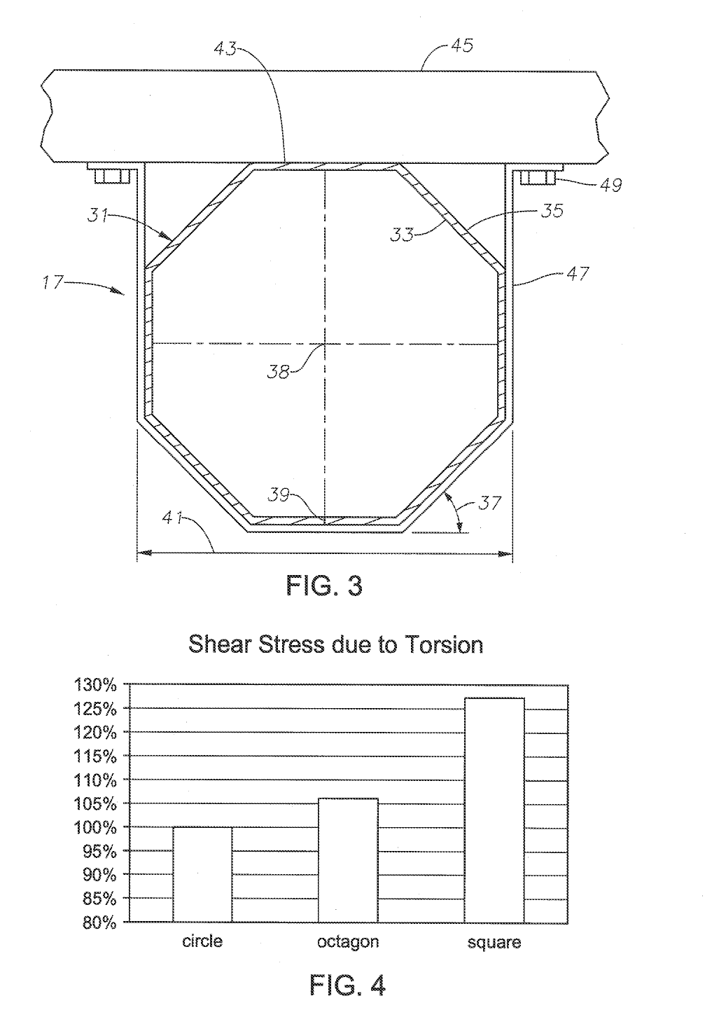

Torque tube 17 has an exterior 31 that mates with bearing cavity 29. Torque tube 17 has an interior 33 that has the same configuration as exterior 31, defining a uniform wall thickness. Referring to FIG. 3, exterior 31 has more than four flat sides 35 and is preferably octagonal. Flat sides 35 are identical in width and join each other at a 45 degree angle 37. Each flat side 35 is in a single plane that extends the full length of torque tube 17. Each flat side 35 is parallel to another one of the flat sides 35.

The wall thickness of torque tube 17 between exterior 31 and interior 33 is quite thin compared to the cross-sectional flat-to-flat dimension 41 of torque tube 17 measured along a line passing through a longitudinal axis 38 from one flat exterior side 35 to an opposite exterior flat side 35 and normal to those flat sides 35. In one embodiment, the wall thickness is in the range from about 0.060 to 0.1 inch and the cross-sectional flat-to-flat dimension 41 between exterior flat sides 35 is about six inches. This results in the cross-sectional flat-to-flat dimension 41 being in a range from about 60 to 100 times greater than the wall thickness, and preferably it is at least 30 times greater. Having a wall thickness of 0.060 inch and a flat-to-flat dimension of 6 inches results in weight of about 4.0 pounds per foot. Torque tube 17 is preferably formed of a galvanized steel alloy, but composite fiber or plastic materials are also feasible.

Torque tube 17 is preferably roll formed. A flat sheet of metal is drawn through an array of rollers (not shown) that gradually bend and form flat sides 35 into an octagonal configuration. The edges of the flat sheet abut and are welded to each other as the octagon shape is achieved, creating a weld seam 39 that is parallel with longitudinal axis 38 of torque tube 17. Weld seam 39 is centered in one of the flat sides 35.

One of the flat sides 35 serves as a datum surface 43 to attach a photo-voltaic panel mount or module clamp 45. Module clamp 45 is illustrated schematically and may have various configurations for mounting one of the photo-voltaic panels 15 (FIG. 1) to torque tube 17 for rotation with torque tube 17. Module clamp 45 may comprise two clamps (only one shown) that are spaced apart from each other along longitudinal axis 38. One of the photo-voltaic panels 15 is retained between the two module clamps 45. Each module clamp 45 may be hat-shaped in cross-section, having a flange that overlies and secures one of the photo-voltaic panels 15 on datum surface 43. Each module clamp 45 fits flush on datum surface 43 and extends laterally past datum surface 43 in opposite directions from axis 38. In this example, datum surface 43 is illustrated facing upward and is opposite the flat side 35 containing weld seam 39.

Each flat side 35 has the same width measured from one edge to the other, and that width is significantly less than the cross-sectional flat-to-flat dimension 41 of torque tube 17 from one flat side 35 to the opposite flat side 35. Being an octagon, the circumferential width of each flat side 35, as well as datum surface 43, is about 41.6% the cross-sectional dimension 41 of torque tube 17. Thus in the preferred embodiment, datum surface 43 is about 2.5 inches wide. Photo-voltaic panels 15 are typically about one meter or 6.5 feet measured perpendicular to torque tube axis 38. Consequently, in one embodiment, the ratio of the width of datum surface 43 to the dimension of panel 15 perpendicular to torque tube axis 38 is about 0.032, and the ratio is preferably not greater than about 0.04. Regardless of the dimensions of panel 15, preferably the width of each flat side 35 is at least one inch.

Module clamp 45 is secured to torque tube 17 in various manners. For example, a generally U-shaped strap 47 with five flat portions is shown extending around the lower portion of torque tube 17. Strap 47 has three lower flat sections 48 that are at the same angle 37 relative to each other as flat sides 35 and fit flush against the three lower flat sides 35 of torque tube 17. A strap leg 50 extends upward from opposite sides of the three lower flat sections 48. Each strap leg 50 joins the three lower flat sections 48 at angle 37 and extends flush along the flat sides 35 that are illustrated in a vertical position in FIG. 3. The upper ends of strap legs 50 are bent 90 degrees into tabs, which are secured to module clamp 45 by fasteners 49. Torque is thus readily transmitted between photo-voltaic panels 15 (FIG. 1) and torque tube 17 via from module clamp 45 and strap 47. The engagement of module clamp 45 and strap 47 is similar to that of a wrench engaging a polygonal nut, because module clamp 45 and strap 47 engage six of the eight flat sides 35 of torque tube 17.

During operation, a control system moves drive shaft 23, which rotates torque tube 17 incrementally, causing solar panels 15 to remain more normal to the sun during the day. Alternately, torque tube 17 could be oriented east-west and remain fixed and non rotating except for seasonal manual rotational adjustments. Further, torque tube 17 could be employed with a completely fixed solar panel array system and never rotate. Even if fixed, torque tube 17 still encounters torque when wind blows across solar panels 15. Torque tube 17 thus must be able to transmit torque and have a high torsional stiffness. Further, because of the distance between posts 21, torque tube 17 must be able to withstand bending due to its own weight as well as the weight of solar panels 15 and snow load.

The configuration of torque tube 17 was selected by analytically comparing an octagonal cross-sectional shape to a cylindrical or circular cross-sectional shape and a square cross-sectional shape. Referring to FIGS. 4-6, analytical studies were made of circular, square and octagonal tubes. In the study, the cross-sectional area of each shape was held equal. Thus a 30 foot long piece of a circular tube or a square tube would weigh the same as a 30 foot long piece of octagonal tube. Also, the wall thickness was held constant for all three shapes. Each tube was analytically subjected to the same amount of torsion. As shown in FIG. 4, the shear stress for a circular tube is less than for an octagonal tube when undergoing the same amount of torsion. The octagonal tube had less shear stress than a square tube when undergoing the same amount of torsion. The graph of FIG. 4 shows the octagonal tube developing about five percent more shear stress than the circular tube. The square tube develops about 28 percent more shear stress than the circular tube.

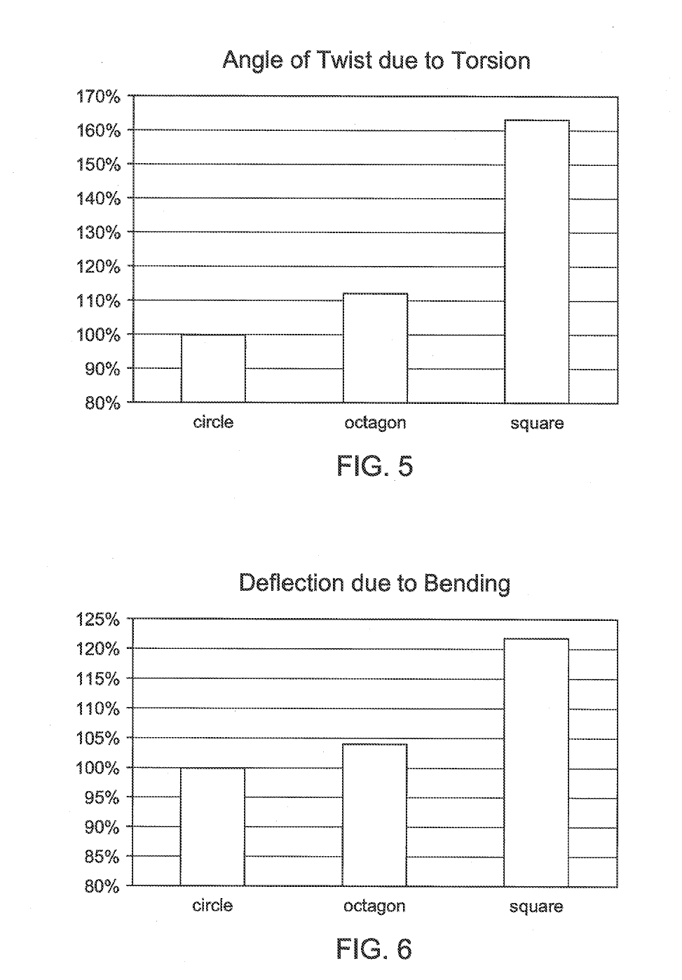

FIG. 5 illustrates the amount of angular twist occurring when the circular, octagonal and square tubes are undergoing the same amount of torsion. The octagonal shaped tube developed about 11 percent more angular twist than the circular tube. The square tube developed about 62 percent more angular twist than the circular tube experiencing the same torsion.

FIG. 6 illustrates the effect of bending forces on the circular, octagonal and square tubes. When subjected to the same bending moments, the octagon tube developed about five percent more deflection than the circular tube. The square tube developed about 22 percent more deflection than the circular tube experiencing the same bending moment.

The study shows clearly that a circular tube is stiffer than both an octagonal tube and a square tube under both torsion and bending moments. The circular tube also develops a lower shear stress under a torsion load than the octagonal tube and the square tube. However, it is difficult to utilize a circular or cylindrical tube as a torque tube in solar panel installations because of the need to mount the solar panels on a common, flat datum surface. An octagonal tube performs better than a square tube for torsion and bending loads. Also, an octagonal tube has a natural datum surface due to its eight flat sides. When considering optimum torque tube shapes, the study shows that increasing the number of flat sides over a square tube causes the tube to perform more like a tube of circular cross-section. Less flat sides or faces cause the tube to behave more like a square tube. The octagon profile is well suited for solar panel array torque tubes because it behaves much like a circular profile while also providing datum faces or surfaces for alignment and transmitting torque. An improved stiffness allows greater spans between posts. Reducing the number of posts lowers system cost.

When compared to a square tube, the octagon tube provides a higher torsional stiffness and lower shear stress; therefore, less material is required in the octagon tube to perform the same task. For example, one commercially available torque tube is a square tube with 4 inch flats and a wall thickness of 0.125 inch. That prior art torque tube has a weight of 6.5 pounds per foot, requiring more material than the preferred embodiment of an octagonal tube, described above, which has a weight of 4.0 pounds per foot. Less material required in the torque tube lowers the system cost. Moreover, when compared to the prior art square tube mentioned, the preferred embodiment octagon tube provides less shear stress, less angle of twist, and higher stiffness due to bending.

The round tube typically requires gussets or brackets to be welded in place to establish a datum for mounting modules. Welding gussets or brackets to the torque tube is not required for the octagon tube, lowering the cost of the system.

While the disclosure has been shown in only one of its forms, it should be apparent that various modifications are possible. For example, the exterior could have a different number of flat sides, such as ten sides.

1. A solar panel array system comprising:
a plurality of vertical posts;
a torque tube supported on upper ends of the vertical posts, the torque tube having a longitudinal axis;
the torque tube having a cross-sectional configuration having an exterior surface with more than four flat sides; and
a photo-voltaic module clamp fastened to one of the flat sides.

2. The system according to claim 1, wherein the exterior surface of the torque tube has eight flat sides.

3. The system according to claim 1, wherein the flat side to which the photo-voltaic mount is fastened has a width that is no greater than 40 percent a cross-sectional dimension of the exterior surface of the torque tube measured along a line passing through the longitudinal axis.

4. The system according to claim 1, wherein each of the flat sides of the exterior surface of the torque tube has an interior surface that is also flat and of the same dimensions as on the exterior surface.

5. The system according to claim 1, wherein the torque tube has a uniform wall thickness.

6. The system according to claim 1, wherein:
the torque tube has a uniform wall thickness; and
a cross-sectional dimension of the exterior surface of the torque tube measured along a line passing through the axis and normal to the flat sides is at least 30 times the wall thickness.

7. The system according to claim 1, wherein a length of the torque tube is greater than 100 feet.

8. The system according to claim 1, further comprising:
a weld seam extending along one of the flat sides parallel with the longitudinal axis.

9. The system according to claim 1, wherein each of the flat sides joins two other of the flat sides and has an identical width.

10. A solar panel array system comprising:
a plurality of vertical posts;
a torque tube supported on upper ends of the posts and having a longitudinal axis;
the torque tube having an octagonal exterior surface and an octagonal interior surface corresponding with the exterior surface; and
wherein the octagonal exterior surface defines at least one flat datum surface for mounting a photo-voltaic panel.

11. The system according to claim 10, further comprising:
a weld seam extending along the exterior surface parallel with the longitudinal axis.

12. The system according to claim 10, wherein the exterior surface defines eight flat sides, each of the flat sides being in a plane parallel with another of the flat sides, and at least one of the flat sides defines the flat datum surface.

13. The system according to claim 10, further comprising:
a photo-voltaic module clamp in abutment with the flat datum surface for securing the photo-voltaic panel;
a strap extending under the torque tube, the strap having a plurality of flat sides that mate with the flat portions of the octagonal exterior surface of the torque tube; and
fasteners that secure upper ends of the strap to the module clamp.

14. The system according to claim 10, wherein each of the flat sides remains in a plane from one end to the other of the torque tube.

15. The system according to claim 10, wherein:
the exterior surface defines eight flat sides, each of the flat sides being in a plane parallel with another of the flat sides, and at least one of the flat sides defines the flat datum surface;
the torque tube has a uniform wall thickness; and
a cross-sectional dimension of the exterior surface of the torque tube measuring along a line passing through the axis from and normal to one of the flat sides and to another of the flat sides is at least 30 times the wall thickness.

16. The system according to claim 10, wherein a length of the torque tube is greater than 100 feet.

17. A solar panel array system comprising:
a plurality of vertical posts;
a bearing mounted on an upper end of each of the posts, the bearing having an octagonal cavity;
a torque tube extending through the bearing along a longitudinal axis, the torque tube having a wall with an octagonal exterior surface that mates with the octagonal cavity of each of the bearings;
the wall of the torque tube having an octagonal interior surface corresponding with the exterior surface, defining a uniform wall thickness;
wherein the octagonal exterior surface defines eight flat sides, each of the flat sides being parallel to another one of the flat sides;
a photo-voltaic module clamp secured to one of the flat sides for rotation with the torque tube; and
a weld seam extending through the wall of the torque tube parallel with the longitudinal axis.

18. The system according to claim 17, further comprising:
a strap extending under the torque tube, the strap having a plurality of flat sides that mate with the flat portions of the octagonal exterior surface of the torque tube; and
fasteners that secure upper ends of the strap to the module clamp.

19. The system according to claim 17, wherein:
a cross-sectional dimension of the torque tube measured along a line passing through the axis from and normal to one of the flat sides of the exterior surface and to another of the flat sides of the exterior surface is at least 30 times the wall thickness.

20. The system according to claim 17, wherein each of the flat sides remains in a plane from one end to the other of the torque tube.
